(19) United States
(12) Patent Application Publication
(10) Pub. No.: US 2026/0114300 A1
(43) Pub. Date: Apr. 23, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Ilbok Lee, Suwon-si (KR); Yanggyoo Jung, Suwon-si (KR)

(73) Assignee: Samsung Electronics Co., Ltd., Suwon-si (KR)

(21) Appl. No.: 19/246,096

(22) Filed: Jun. 23, 2025

(30) Foreign Application Priority Data
Oct. 18, 2024 (KR) 10-2024-0142964

(51) Int. Cl. H01L 23/00; H01L 23/538; H01L 25/065

(52) U.S. Cl. CPC H10W 70/611; H10W 90/00; H10W 90/401; H10W 72/072; H10W 72/222; H10W 72/234; H10W 72/237; H10W 72/241; H10W 72/248; H10W 72/252; H10W 72/257; H10W 72/263; H10W 72/267; H10W 90/724

(57) ABSTRACT

A semiconductor package includes a first semiconductor chip having a dummy region, a connection region, and a lower conductive structure disposed below the connection region; bump structures including a first bump structure on the lower conductive structure and a second bump structure below the dummy region; an interposer having the first semiconductor chip mounted thereon and upper conductive structures disposed in an upper portion thereof; connection bumps disposed on upper portions of the upper conductive structures: including a first connection bump in contact with the first bump structure and a second connection bump in contact with the second bump structure; and at least one second semiconductor chip mounted on the interposer adjacent to the first semiconductor chip. The second bump structure includes a portion with a tapering width toward the second connection bump, an end of the second bump structure is inserted into the second connection bump.

### CROSS-REFERENCE TO RELATED APPLICATION(S)

This application claims the benefit under 35 USC 119(a) of Korean Patent Application No. 10-2024-0142964 filed on Oct. 18, 2024, in the Korean Intellectual Property Office, the entire disclosure of which is incorporated herein by reference for all purposes.

### BACKGROUND

The description herein generally relates to a semiconductor package and a method of manufacturing the same.

Semiconductor devices mounted on electronic devices are required to be miniaturized, high-performance, and high-capacity. To achieve this, semiconductor packages that interconnect semiconductor chips disposed horizontally are being developed.

### SUMMARY

Example embodiments provide a semiconductor package having improved reliability.

According to example embodiments, a semiconductor package includes an interposer substrate including upper conductive structures disposed in an upper portion thereof; connection bumps disposed on the upper conductive structures and including a first connection bump and a second connection bump; a plurality of semiconductor chips including a first semiconductor chip and at least one second semiconductor chip disposed side by side on the interposer substrate; and bump structures disposed on respective lower portions of the first semiconductor chip and the at least one second semiconductor chip and aligned with the respective connection bumps. Each of the first semiconductor chip and the at least one second semiconductor chip includes a first side and a second side; a dummy region including a corner portion formed at a point at which the first side and the second side intersect; and a connection region disposed between the first side and the second side and continuous with the dummy region. The bump structures include a first bump structure disposed on the connection region and contacting the first connection bump; and a second bump structure disposed on the dummy region, contacting the second connection bump, and including a material different from a material of the first bump structure.

According to example embodiments, a semiconductor package includes a first semiconductor chip having a dummy region and a connection region, and including a lower conductive structure disposed below the connection region; bump structures including a first bump structure on the lower conductive structure and a second bump structure below the dummy region; an interposer substrate having the first semiconductor chip mounted thereon and including upper conductive structures disposed in an upper portion thereof; connection bumps disposed on respective upper portions of the upper conductive structures, and including a first connection bump in contact with the first bump structure and a second connection bump in contact with the second bump structure; and at least one second semiconductor chip mounted side by side with the first semiconductor chip, on the interposer substrate. The second bump structure includes a portion with a width becoming narrower toward the second connection bump, and an end of the second bump structure is inserted into the second connection bump.

According to example embodiments, a semiconductor package includes an interposer substrate including upper conductive structures disposed in an upper portion thereof; a first semiconductor chip disposed on the interposer substrate, having a dummy region and a connection region, and including lower conductive structures disposed below the connection region and facing at least a portion of the upper conductive structures; at least one second semiconductor chip disposed side by side with the first semiconductor chip, on the interposer substrate; connection bumps disposed on respective upper portions of the upper conductive structures, and including a first connection bump overlapping the connection region and a second connection bump overlapping the dummy region; and bump structures including a first bump structure disposed on respective lower portions of the lower conductive structures and contacting the first connection bump, and a second bump structure disposed below the dummy region and vertically penetrating through at least a portion of the second connection bump. The second bump structure includes a material different from a material of the second connection bump.

### BRIEF DESCRIPTION OF FIGURES

The above and other aspects, features, and advantages of the present disclosure will be more clearly understood from the following detailed description, taken in conjunction with the accompanying drawings, in which:

FIG. 1A is a schematic diagram of a semiconductor package, consistent with embodiments of the present disclosure;

FIG. 1B is a cross-sectional view illustrating a semiconductor package taken along line I-I′ of FIG. 1A, consistent with embodiments of the present disclosure;

FIG. 2A is a partial enlarged view illustrating area ‘A’ of FIG. 1B, consistent with embodiments of the present disclosure;

FIG. 2B is a partial enlarged view illustrating area ‘B’ of FIG. 2A, consistent with embodiments of the present disclosure;

FIG. 2C is a partial enlarged view illustrating area ‘C’ of FIG. 2A, consistent with embodiments of the present disclosure;

FIG. 3 is a partial enlarged view of a semiconductor package according to an example embodiment;

FIG. 4A is a partial enlarged view of a semiconductor package, consistent with embodiments of the present disclosure;

FIG. 4B is a partial enlarged view of a semiconductor package, consistent with embodiments of the present disclosure;

FIG. 4C is a partial enlarged view of a semiconductor package, consistent with embodiments of the present disclosure;

FIG. 4D is a partial enlarged view of a semiconductor and a partial enlarged view illustrating area ‘D’of FIG. 4C, consistent with embodiments of the present disclosure;

FIG. 5 is a schematic diagram of a semiconductor package, consistent with embodiments of the present disclosure;

FIG. 6A is a partial enlarged view of a semiconductor, consistent with embodiments of the present disclosure;

FIG. 6B is a partial enlarged view illustrating area ‘B’ of FIG. 6A, consistent with embodiments of the present disclosure;

FIGS. 7 to 9 are cross-sectional views illustrating a process sequence to describe a method of manufacturing a semiconductor package, consistent with embodiments of the present disclosure; and

FIGS. 10 to 12 are cross-sectional views illustrating a process sequence to describe a method of manufacturing a semiconductor package, consistent with embodiments of the present disclosure.

### DETAILED DESCRIPTION

Hereinafter, terms such as “on,” “upper,” “upper surface,” “below,” “lower,” “low surface,” “side,” “side surface,” “top,” “bottom,” and the like are understood to refer to the drawings, except in cases where they are separately referred to by being indicated with drawing symbols. Terms such as “upper,” “middle,” “intermediate,” and “lower” may also be replaced with other terms, such as “first,” “second,” and “third,” and used to describe components of the specification. Terms such as “first,” “second,” and “third” may be used to describe various components, but the components are not limited by the terms, and a “first component” may be named a “second component.”

Hereinafter, example embodiments will be described with reference to the attached drawings.

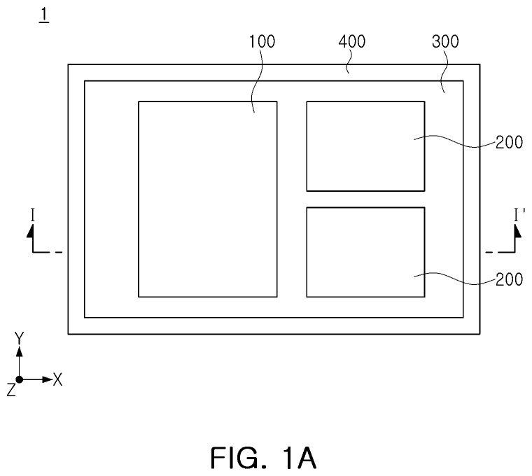

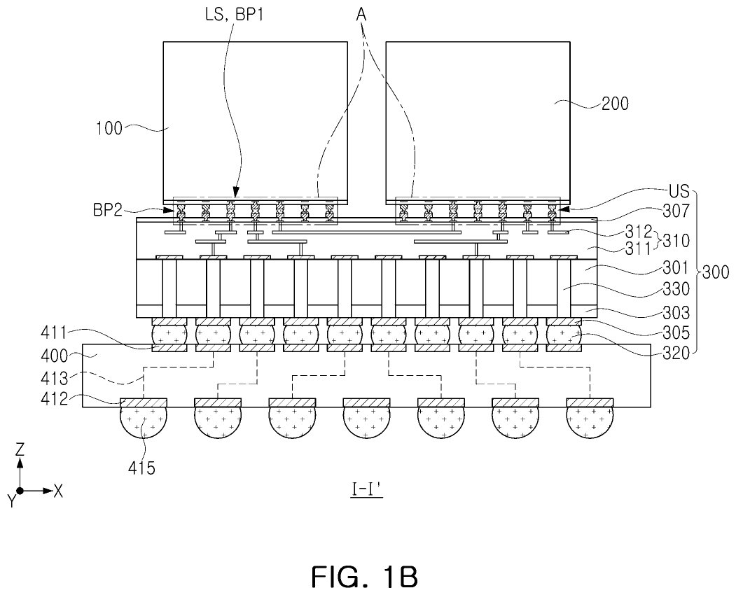

FIG. 1A is a plan view illustrating a semiconductor package according to an example embodiment.

FIG. 1B is a cross-sectional view illustrating a semiconductor package along the line I-I′ of FIG. 1.

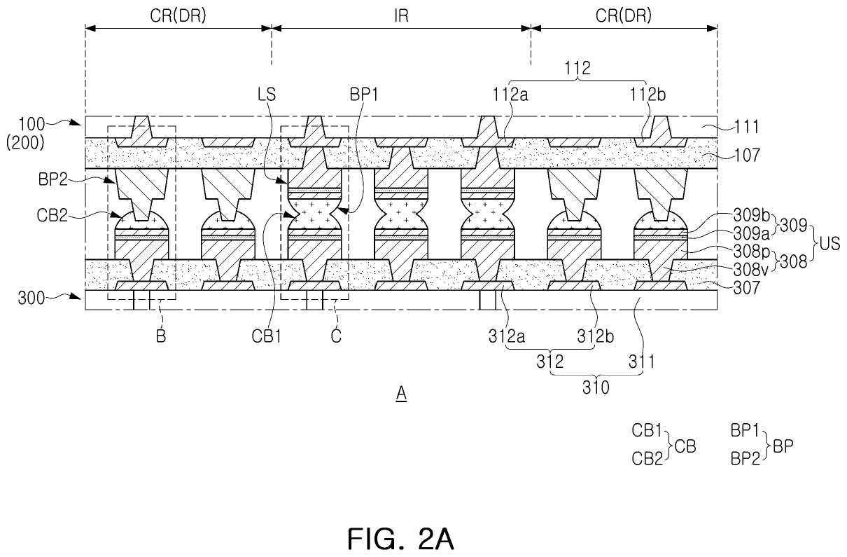

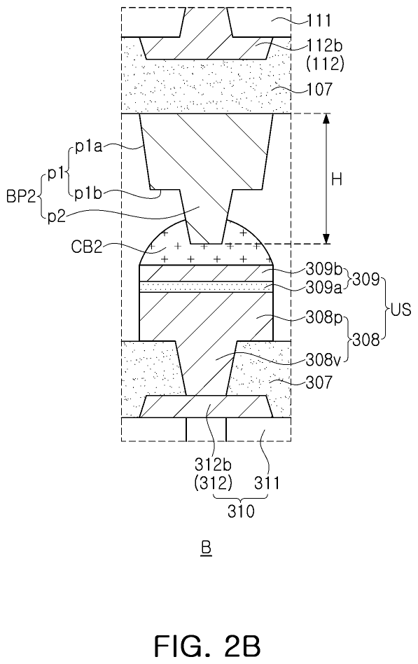

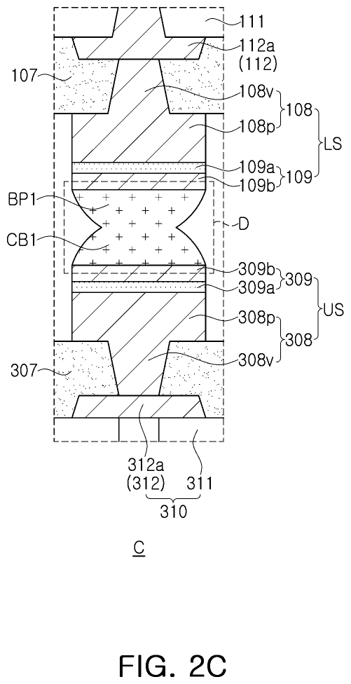

FIG. 2A is a partial enlarged view illustrating area ‘A’of FIG. 1B.

FIG. 2B is a partial enlarged view illustrating area ‘B’of FIG. 2A.

FIG. 2C is a partial enlarged view illustrating area ‘C’of FIG. 2A.

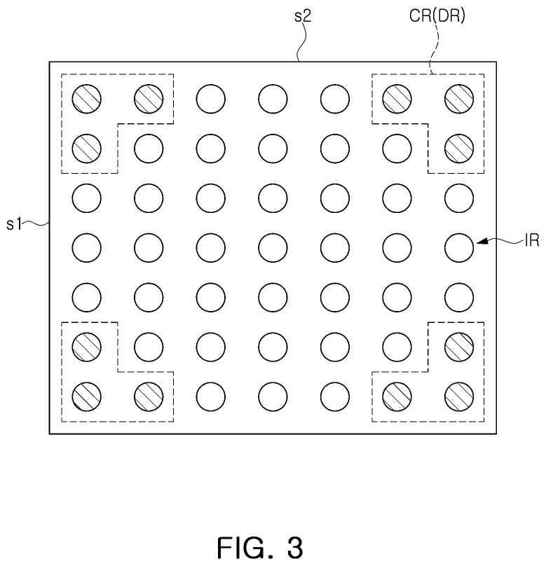

FIG. 3 is a partial enlarged view of a semiconductor package according to an example embodiment. FIG. 3 is a plan view illustrating a bump structure disposed below each of a plurality of semiconductor chips.

Reference is now made to FIGS. 1A to 3, which illustrates a schematic diagram of a semiconductor package, consistent with embodiments of the present disclosure. According to some embodiments, semiconductor package (1) of an example embodiment may include a package substrate (400), an interposer substrate (300), and a plurality of semiconductor chips (100, 200). The plurality of semiconductor chips (100, 200) may include a first semiconductor chip (100) and at least one second semiconductor chip (200) disposed side by side on an interposer substrate (300).

According to some embodiments, he first semiconductor chip (100) may include a logic chip such as a central processor (CPU), a graphic processor (GPU), a field programmable gate array (FPGA), a digital signal processor, an encryption processor, a microprocessor, a microcontroller, an analog-to-digital converter, an ASIC, etc. In an example embodiment, the first semiconductor chip (100) may be referred to as a first semiconductor chip structure (100).

According to some embodiments, the at least one second semiconductor chip (200) may include a chip that performs substantially the same or similar function as the first semiconductor chip (100), but is not limited thereto. The at least one second semiconductor chip (200) may include a high-capacity memory device such as, for example, a high bandwidth memory (HBM). In an example embodiment, the at least one second semiconductor chip (200) may be referred to as a second semiconductor chip structure (200) or the plurality of second semiconductor chips 200.

For example, each of the plurality of semiconductor chips (100, 200) may include a first side (s1) and a second side (s2) (see FIG. 3). According to some embodiments, the plurality of semiconductor chips (100, 200) may be disposed side by side on interposer substrate (300). Each of the plurality of semiconductor chips (100, 200) may include a dummy region (DR) including a corner portion formed at a point at which the first side (s1) and the second side (s2) intersect, and a connection region (IR) disposed between the first side (s1) and the second side (s2) and adjacent to the dummy region (DR). According to some embodiments, the dummy region (DR) may be referred to as a corner region (CR).

According to some embodiments, the connection region (IR) may be a region where an electrical connection path is formed between each of the plurality of semiconductor chips (100, 200) and the interposer substrate (300). The dummy region (DR) may be a region where an electrical connection path is not formed between each of the plurality of semiconductor chips (100, 200) and the interposer substrate (300). According to some embodiments, each of the plurality of semiconductor chips (100, 200) may include an interlayer insulating layer (111) and a wiring structure (112). When the wiring structure (112) is formed of a multilayer wiring structure, wiring patterns of different layers may be connected to each other through contact vias. The wiring structure (112) may include a first wiring structure (112a) and a second wiring structure (112b). According to some embodiments, the first wiring structure (112a) may be a wiring structure that forms an electrical connection path between each of the plurality of semiconductor chips (100, 200) and the interposer substrate (300). For example, the first wiring structure (112a) may be formed on a connection region, for example connection region (IR) of FIG. 3. According to some embodiments, the second wiring structure (112b) may be a dummy wiring structure that does not form an electrical connection path between each of the plurality of semiconductor chips (100, 200) and the interposer substrate (300). For example, the second wiring structure (112b) may be formed on a dummy region, for example dummy region (DR) of FIG. 3.

According to some embodiments, each of the plurality of semiconductor chips (100, 200) may further include a lower protective layer (107) on the interlayer insulating layer (111). The lower protective layer (107) may be disposed on the interlayer insulating layer (111) and may have an open portion that exposes at least a portion of the lowermost wiring pattern of the wiring structures (112). According to some embodiments, the lower protective layer (107) may be referred to as a lower insulating layer (107). According to some embodiments, each of the plurality of semiconductor chips (100, 200) may further include a lower conductive structure (LS) on the connection region (IR).

According to some embodiments, the lower conductive structure (LS) may include a conductive layer (108) that at least partially fills the open portion and a barrier layer (109) on the conductive layer (108). The conductive layer (108) may include a via portion (108v) that fills the open portion and contacts the lowermost wiring pattern, and a pad portion (108p) on the via portion (108v). The barrier layer (109) may include a first barrier layer (109a) on the pad portion (108p) and a second barrier layer (109b) on the first barrier layer (109a). The conductive layer (108) and the second barrier layer (109b) may include the same conductive material. For example, the conductive layer (108) and the second barrier layer (109b) may include copper (Cu). The first barrier layer (109a) may include a different conductive material from the conductive layer (108) and the second barrier layer (109b). For example, the first barrier layer (109a) may include nickel (Ni).

According to some embodiments, a plurality of bump structures (BP) may be disposed below each of the plurality of semiconductor chips (100, 200). The plurality of bump structures (BP) may include a first bump structure (BP1) on the connection region (IR) and a second bump structure (BP2) on the dummy region (DR).

According to some embodiments, the first bump structure (BP1) may be disposed below the lower conductive structure (LS). For example, the first bump structure (BP1) may be disposed on the lower surface of the barrier layer (109). The first bump structure (BP1) may comprise, for example, tin (Sn), indium (In), bismuth (Bi), antimony (Sb), copper (Cu), silver (Ag), zinc (Zn), lead (Pb), or an alloy of these materials. According to an example embodiment, the first bump structure (BP1) may comprise a conductive pillar and a solder ball combined.

According to some embodiments, the second bump structure (BP2) may be disposed on the lower portion of the lower protective layer (107). For example, the second bump structure (BP2) may be formed on the lower surface of the lower protective layer (107) on the dummy region (DR). The second bump structure (BP2) may include a first portion (p1) on the lower protective layer (107) and a second portion (p2) protruding downward from the lower surface of the first portion (p1). The first portion (p1) may include a side portion (p1a) and a connecting portion (p1b) extending from the side portion (p1a) to the second portion (p2). According to an example embodiment, the first portion (p1) may be referred to as a horizontal portion, and the second portion (p2) may be referred to as a protrusion.

The maximum width in the horizontal direction (for example, X or Y direction) of the second portion (p2) may be smaller than the maximum width in the horizontal direction of the first portion (p1). The width in the horizontal direction of each of the first and second portions (p1, p2) may decrease as it approaches the interposer substrate (300). The second bump structure (BP2) may include a different conductive material from the first bump structure (BP1). For example, the second bump structure (BP2) may be selected from the group consisting of copper (Cu), nickel (Ni), or gold (Au).

The vertical thickness (H) of the second bump structure (BP2) may be approximately 15 μm or more. According to some embodiments, the thickness (H) may be in a range of approximately 15 μm to approximately 25 μm. According to some embodiments, the thickness (H) may be in a range of approximately 20 μm to approximately 25 μm. According to some embodiments, the thickness (H) may be in a range of about 22 μm to about 25 μm.

According to some embodiments, the package substrate (400) may be a support substrate on which the interposer substrate (300) is mounted, and may be a semiconductor package substrate including a printed circuit board (PCB), a ceramic substrate, a glass substrate, a tape wiring substrate, etc. The package substrate (400) may include a lower pad (412), an upper pad (411), and a wiring circuit (413). An external connection bump (415) connected to the lower pad (412) may be disposed on the lower surface of the package substrate (400). The external connection bump (415) may include, for example, a solder ball.

According to some embodiments, interposer substrate (300) may include a semiconductor substrate (301), a lower protection layer (303), a lower pad (305), an interconnection structure (310), a conductive bump (320), and a silicon through-via (330). The first semiconductor chip (100) and at least one second semiconductor chip (200) may be electrically connected to each other via an interposer substrate (300).

According to some embodiments, semiconductor substrate (301) may be formed of, for example, any one of a silicon, organic, plastic, or glass substrate. According to some embodiments, when the semiconductor substrate (301) is a silicon substrate, the interposer substrate (300) may be referred to as a silicon interposer. According to some embodiments, when the semiconductor substrate (301) is an organic substrate, the interposer substrate (300) may be referred to as a panel interposer.

According to some embodiments, a lower protective layer (303) may be disposed on a lower surface of the semiconductor substrate (301), and a lower pad (305) may be disposed below the lower protective layer (303). The lower pad (305) may be connected to a silicon through-via (330). The interposer substrate (300) may be electrically connected to the package substrate (400) through conductive bumps (320) disposed below the lower pad (305).

According to some embodiments, the interconnection structure (310) may be disposed on the upper surface of the semiconductor substrate (301) and may include an interlayer insulating layer (311) and a single-layer or multi-layer wiring structure (312). When the interconnection structure (310) is formed of a multi-layer wiring structure, wiring patterns of different layers may be connected to each other through contact vias. The wiring structure (312) may include a first wiring structure (312a) and a second wiring structure (312b). The first wiring structure (312a) may be a wiring structure that forms an electrical connection path between each of the first semiconductor chip (100) and at least one second semiconductor chip (200) and the interposer substrate (300). The second wiring structure (312b) may be defined as a dummy wiring structure that does not form an electrical connection path between each of the first semiconductor chip (100) and at least one second semiconductor chip (200) and the interposer substrate (300).

According to some embodiments, the interposer substrate (300) may further include an upper protective layer (307) on the interconnection structure (310). The upper protective layer (307) may be disposed on the interlayer insulating layer (311) and may have an open portion that exposes at least a portion of the uppermost wiring pattern of the wiring structure (312). According to an example embodiment, the upper protective layer (307) may be referred to as a passivation layer.

According to some embodiments, the interposer substrate (300) may further include an upper conductive structure (US). The upper conductive structure (US) may include a conductive layer (308) at least partially filling the open portion and a barrier layer (309) on the conductive layer (308). The conductive layer (308) may include a via portion (308v) filling the open portion and contacting the uppermost wiring pattern, and a pad portion (308p) on the via portion (308v). The barrier layer (309) may include a first barrier layer (309a) on the pad portion (308p) and a second barrier layer (309b) on the first barrier layer (309a). The conductive layer (308) and the second barrier layer (309b) may include the same conductive material. For example, the conductive layer (308) and the second barrier layer (309b) may include copper (Cu). The first barrier layer (309a) may include a different conductive material from the conductive layer (308) and the second barrier layer (309b). For example, the first barrier layer (309a) may include nickel (Ni).

According to some embodiments, the silicon through via (330) may extend from the upper surface to the lower surface of the semiconductor substrate (301). In addition, the silicon through via (330) may extend into the interior of the interconnection structure (310) and be electrically connected to the multilayer wiring structure (312). According to an example embodiment, the interposer substrate (300) may include only the interconnection structure therein and may not include the silicon through via (330).

Referring back to FIG. 3, the interposer substrate (300) may be used for the purpose of converting or transmitting an input electrical signal between the package substrate (400) and the first semiconductor chip (100) or at least one second semiconductor chip (200). Accordingly, the interposer substrate (300) may not include components such as active components or passive components. In addition, according to some embodiments, the interconnection structure (310) may be disposed below the silicon through via (330). For example, the positional relationship between the interconnection structure (310) and the silicon through via (330) may be related to one another.

According to some embodiments, a plurality of connection bumps (CB) may be disposed on the upper side of the interposer substrate (300). Each of the plurality of connection bumps (CB) may be disposed on each of the upper conductive structures (US). For example, each of the plurality of connection bumps (CB) may be disposed on the upper surface of the barrier layer (309). Each of the plurality of connection bumps (CB) may include, for example, tin (Sn), indium (In), bismuth (Bi), antimony (Sb), copper (Cu), silver (Ag), zinc (Zn), lead (Pb), and/or alloys thereof. According to an example embodiment, each of the plurality of connection bumps (CB) may comprise a combined conductive pillar and solder ball.

According to some embodiments, for example as shown in FIG. 2A, the plurality of connection bumps (CB) may be defined to include a first connection bump (CB1) overlapping the connection region (IR) and a second connection bump (CB2) overlapping the dummy region (DR). For example, the first connection bump (CB1) and the first bump structure (BP1) may face each other, or may be aligned, for example in along the z-direction, and the second connection bump (CB2) and the second bump structure (BP2) may face each other, or be aligned, for example along the z-direction.

According to some embodiments, for example s shown in FIG. 2C, the first bump structure (BP1) may be in contact with the first connection bump (CB1). Accordingly, each of the plurality of semiconductor chips (100, 200) may be electrically connected to the upper conductive structure (US) through the first bump structure (BP1) and the first connection bump (CB1).

According to some embodiments, for example as shown in FIG. 2B, the second bump structure (BP2) may penetrate at least a portion of the second connection bump (CB2). According to some embodiments, an end portion of the second bump structure (BP2), for example, the second portion (p2), may penetrate at least a portion of the second connection bump (CB2). According to some embodiments, the second connection bump (CB2) may surround at least a portion of a side portion of the second portion (p2). In an example embodiment, the lower surface of the second portion (p2) may be spaced apart from the upper surface of the upper conductive structure (US).

According to some embodiments, by forming a bump structure (for example, BP2) having a protruding end on the dummy region (DR) of a plurality of semiconductor chips (100, 200), a semiconductor package (1) with improved reliability may be provided. For example, by forming an end (for example, p2) of the bump structure to penetrate at least a part of a connection bump (for example, CB2) of an interposer substrate (300), a semiconductor package (1) with improved reliability may be provided.

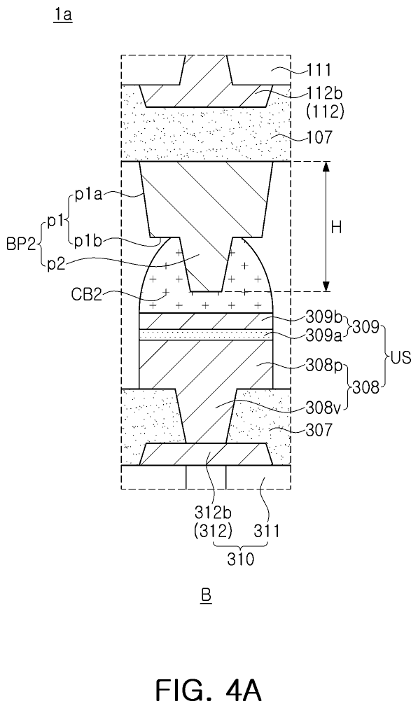

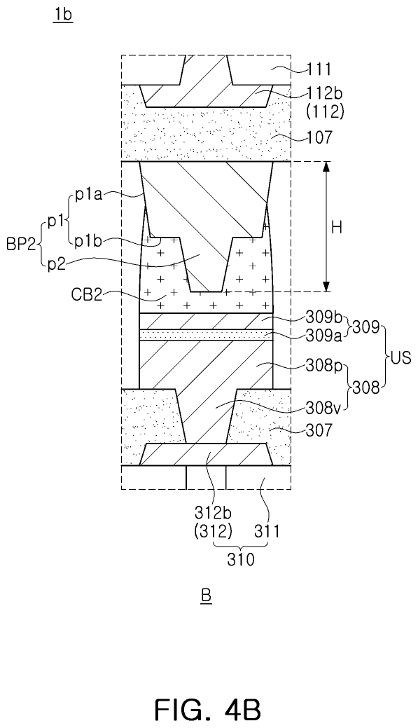

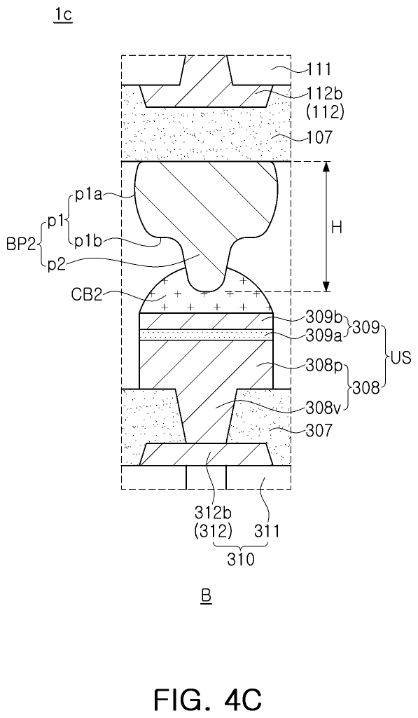

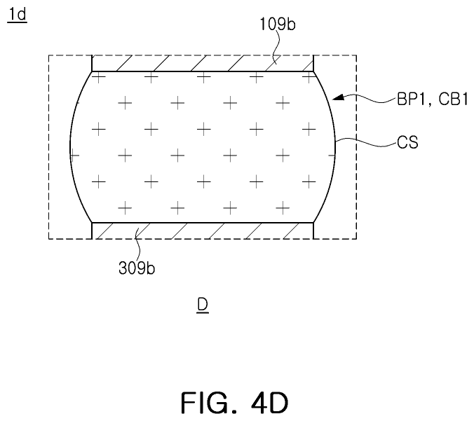

Reference is now made to FIGS. 4A to 4D, which illustrate enlarged views of a portion of a semiconductor package according to embodiments of the present disclosure.

Referring to FIG. 4A, semiconductor package (1a) may, for example, include similar or the same components and structure as semiconductor package (1), as described above with respect to FIGS. 1A through 3. According to some embodiments, semiconductor package (1a) may comprise second connection bump (CB2) that completely surrounds the second portion (p2) of the second bump structure (BP2).

According to some embodiments, second connection bump (CB2) may entirely or completely surround the second portion (p2) of the second bump structure (BP2) and may contact at least a portion of the connecting portion (p1b) of the first portion (p1).

Referring to FIG. 4B, the semiconductor package (1b) may, for example, include similar or the same components and structure as semiconductor package 1, as described above with respect to FIGS. 1A through 4A. According to some embodiments, semiconductor package 1b may comprise a second connection bump (CB2) that contacts at least a portion of the first portion (p1) of the second bump structure (BP2).

According to some embodiments, second connection bump (CB2) may completely cover or surround the second portion (p2) of the second bump structure (BP2) and the connecting portion (p1b) of the first portion (p1), and may contact a lower area of the side portion (p1a) of the first portion (p1).

Referring to FIG. 4C, semiconductor package (1c) may, for example, include similar or the same components and structure as semiconductor package (1), as described above with respect to FIGS. 1A through 4B. According to some embodiments, semiconductor package (1c) may comprise a second bump structure (BP2) having a curved portion.

According to some embodiments, each of the first portion (p1) and the second portion (p2) may include a curved portion. For example, the side portion (p1a) of the first portion (p1) may have a curved surface having a convex shape in a horizontal direction (for example, X and/or Y direction). According to some embodiments, the second portion (p2) may have a blunt or pointed shape in a vertical direction. According to some embodiments, the connecting portion (p1b) of the first portion (p1) may have a steeper slope as it approaches the second portion (p2).

Referring to FIG. 4D, the semiconductor package (1d) may, for example, include similar or the same components and structure as semiconductor package (1), as described above with respect to FIGS. 1A through 4C. According to some embodiments, semiconductor package (1d) may comprise a first bump structure (BP1) and a first connection bump (CB1) forming a single curved portion.

According to some embodiments, the first bump structure (BP1) and the first connection bump (CB1) may be in contact with each other to form a single curved portion (CS). The side surface of the curved portion (CS) may be formed to protrude in a horizontal direction (for example, in the X or Y direction) more than the side surface of each of the upper connection structure US and lower connection structures (LS).

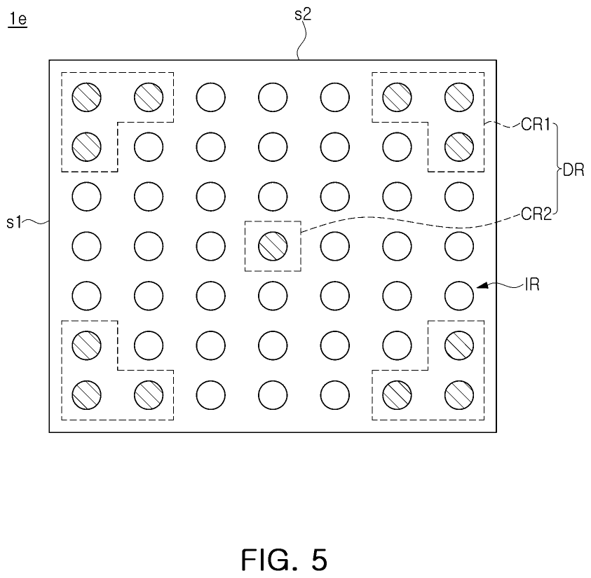

Reference is now made to FIG. 5, which is a partially enlarged view of a semiconductor package according to embodiments of the present disclosure. According to some embodiments, FIG. 5 is a schematic diagram of a bump structure disposed on the lower portion of each of a plurality of semiconductor chips.

According to some embodiments, the semiconductor package (le) may, for example, include similar or the same components and structure as semiconductor package (1), as described above with respect to FIGS. 1 through 4D. According to some embodiments, semiconductor package (1e) may comprise a dummy region (DR) including a central portion (CR2) disposed in the substantially middle of the semiconductor package, or substantially where the midpoints of the first side (s1) and the second side (s2) meet.

According to some embodiments, a portion of the dummy region (DR) may be formed at a point at which the first side (s1) and the second side (s2) intersect may be referred to as a corner portion (CR1). In the present embodiment, a second bump structure (e.g., second bump portion (BP2) of FIG. 2A) may be formed on the central portion (CR2) and at the corner portion (CR1). According to some embodiments, a second wiring structure (e.g., second wiring structure (112b) of FIG. 2A) may be formed on the central portion (CR2).

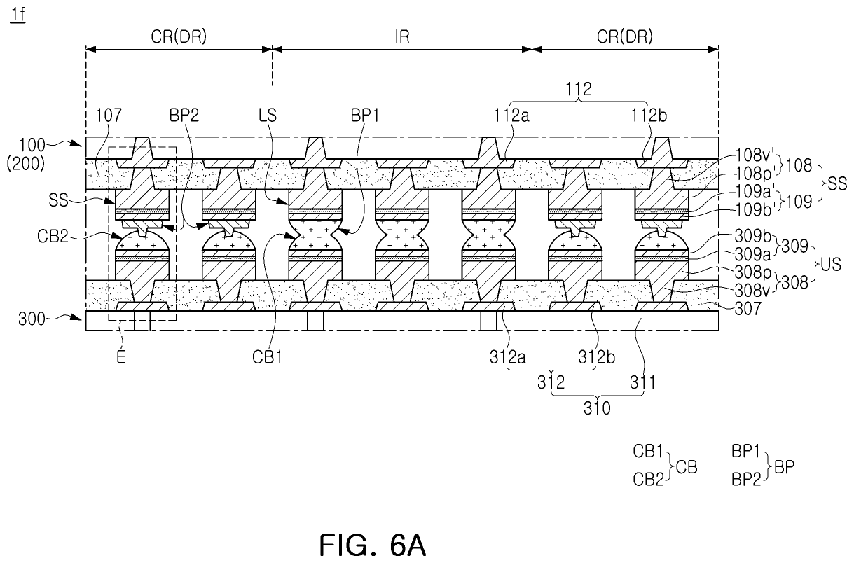

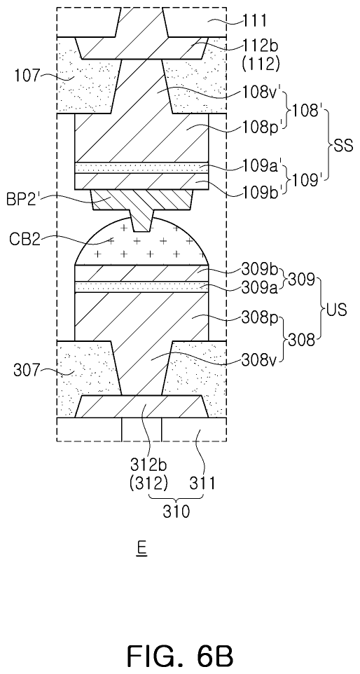

Reference is now made to FIGS. 6A and 6B, which are enlarged views of a portion of a semiconductor package according to an example embodiment. FIG. 6B is an enlarged view of a portion illustrating area ‘E’ of FIG. 6A, according to some embodiments of the present disclosure.

As illustrated in FIGS. 6A and 6B, the semiconductor package (1f) may, for example, include similar or the same components and structure as semiconductor package (1), as described above with respect to FIGS. 1A through 5. According to some embodiments, semiconductor package (1f) may comprise a support structure (SS) on the dummy region (DR).

According to some embodiments, support structure (SS) on the dummy region (DR) may be formed parallel to the lower conductive structure (LS) on the connection region (IR). According to some embodiments, the support structure (SS) and the lower conductive structure (LS) may be at substantially the same distance from the lower surface of the lower insulating layer (107).

According to some embodiments, support structure (SS) may be substantially the same as or similar to the lower conductive structure (LS), for example, as described above with reference to FIGS. 1A to 5. For example, the support structure (SS) may include a conductive layer (108′) that at least partially fills an open portion of the lower insulating layer (107) and a barrier layer (109′) on the conductive layer (108′). The conductive layer (108′) may include a via portion (108v′) that fills the open portion and contacts the lowermost wiring pattern, and a pad portion (108p′) on the via portion (108v′). The barrier layer (109′) may include a first barrier layer (109a′) on the pad portion (108p′) and a second barrier layer (109b′) on the first barrier layer (109a′).

According to some embodiments, each of the conductive layer (108′) and the second barrier layer (109b′) may include the same conductive material as each of the conductive layer (e.g., conductive layer (108) of FIG. 2C) and the second barrier layer (e.g., second barrier layer (109b) of FIG. 2C) of the lower conductive structure (LS). The first barrier layer (109a′) may include the same conductive material as the first barrier layer (e.g., first barrier layer (109a) of FIG. 2C) of the lower conductive structure (LS).

According to some embodiments, a second bump structure (BP2′) may be disposed on the support structure (SS). For example, the second bump structure (BP2′) may be disposed on the lower surface of the second barrier layer (109b′) of the support structure (SS). The vertical thickness of the second bump structure (BP2′) may be approximately 10 μm or less. According to some embodiments, the thickness may be in the range of approximately 3 μm to approximately 10 μm. According to some embodiments, the thickness may be in the range of about 5 μm to about 10 μm.

According to some embodiments, other features of the second bump structure (BP2′) may, for example, include similar or the same components and structure as second bump structure (BP2), as described above with respect to FIGS. 1A through 5.

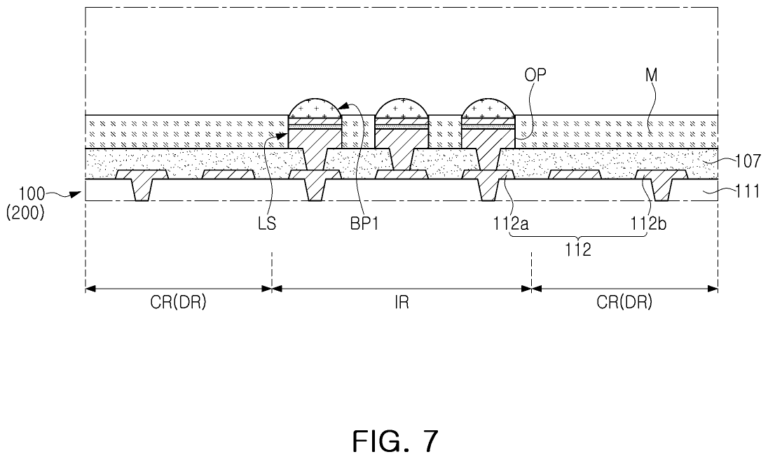

Reference is now made to FIGS. 7 through 9, which illustrate cross-sectional views illustrating a method of manufacturing a semiconductor package (1) according to an example embodiment according to a process sequence.

As shown in FIG. 7, a lower conductive structure (LS) may be formed on a connection region (IR) of each of a first semiconductor chip (100) and at least one second semiconductor chip (200).

A plurality of semiconductor chips (100, 200) including an interlayer insulating layer (111), a wiring structure (112) within the interlayer insulating layer (111), and a lower insulating layer (107) covering the wiring structure (112) on the interlayer insulating layer (111) may be provided. According to some embodiments, each of the plurality of semiconductor chips (100, 200) may be disposed such that the lower surface of the lower insulating layer (107) faces up.

According to some embodiments, a plurality of open portion may be formed in the lower insulating layer (107) such that at least a portion of the wiring structure (112) (or the first wiring structure (112a)) on the connection region (IR) is exposed. Subsequently, a mask (M) having openings (OP) may be formed on the lower insulating layer (107) so as to expose the plurality of open portions.

According to some embodiments, a conductive layer (e.g., conductive layer (308) of FIG. 2A) and a barrier layer (e.g., barrier layer (309) of FIG. 2A) may be sequentially formed in the openings (OP) to form a lower conductive structure (LS). Each of the conductive layer (308) and the barrier layer (309) may be formed by an electrolytic plating method.

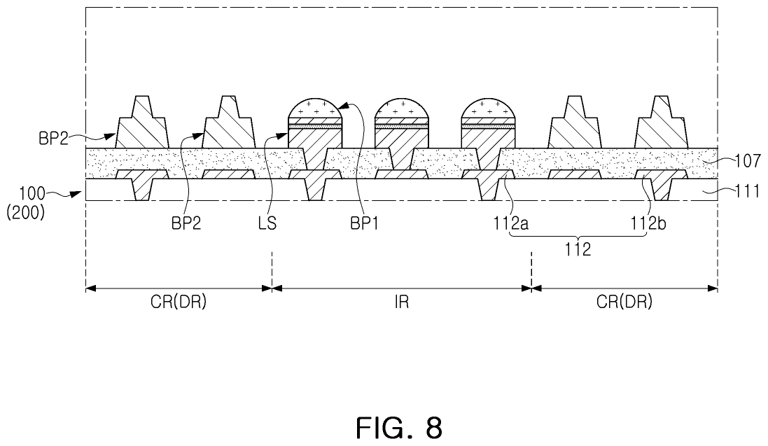

Referring to FIG. 2A together with FIG. 8, the conductive layer (308) may have a via portion (308a) filling each of the plurality of open portions and a pad portion (308b) on the via portion (308a). The barrier layer (309) may have a lower layer (309a) and an upper layer (309b). The conductive layer (308) may include copper (Cu), the lower layer (309a) may include nickel (Ni), and the upper layer (309b) may include copper (Cu).

According to some embodiments, first bump structure (BP1) may be formed on the lower conductive structure (LS).

Referring to FIG. 8, a second bump structure (BP2) may be formed on the dummy region (DR).

According to some embodiments, the mask (M) is removed, and the second bump structure (BP2) may be formed on the dummy region (DR). The second bump structure (BP2) may be formed using a wire bonder that provides a conductive material on the lower insulating layer (107). The conductive material may be any material capable of forming a bump structure. The conductive material may be selected from the group consisting of, for example, copper (Cu), nickel (Ni), or gold (Au).

Referring to FIG. 2B together with FIG. 8, the second bump structure (BP2) formed by the wire bonder may have a first portion (p1) on the lower insulating layer (107) and a second portion (p2) on the first portion (p1). The second portion (p2) may have a shape that protrudes upward from the upper surface of the first portion (p1). The boundary between the first and second portions (p1, p2) may not be distinguished.

According to some embodiments, based on the upper surface of the lower insulating layer (107), the uppermost level of the second bump structure (BP2) may be substantially the same as the uppermost level of the first bump structure (BP1).

Referring to FIG. 5 together with FIG. 8, the second bump structure (BP2) may also be provided at the central portion (CR2) of each of the plurality of semiconductor chips (100, 200). According to some embodiments, a semiconductor package (1d) may be provided.

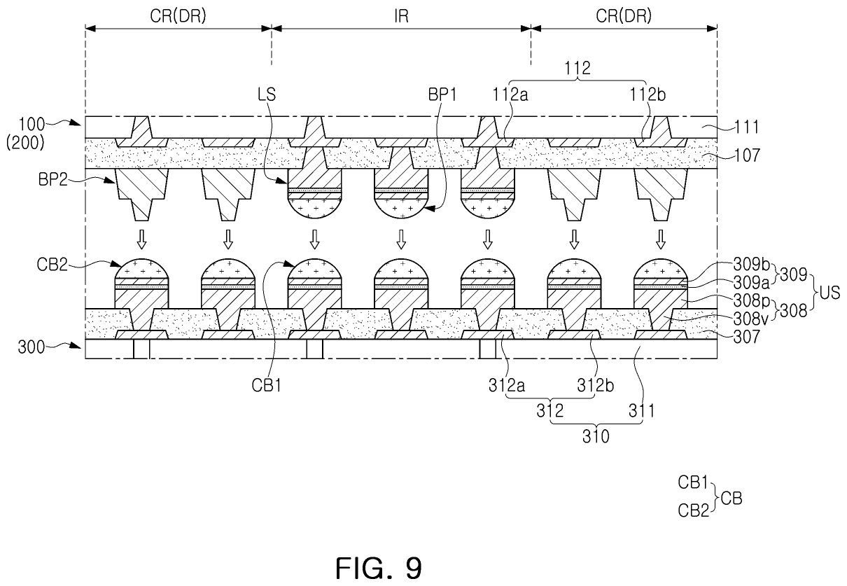

Referring to FIG. 9, an interposer substrate (300) having an upper conductive structure (US) formed thereon may be provided, and first and second connection bumps (CB1, CB2) may be formed on the upper conductive structure (US). Subsequently, a plurality of semiconductor chips (100, 200) may be mounted side by side on the interposer substrate (300). According to some embodiments, the first bump structure (BP1) may be in contact with the first connection bump (CB1), and the second bump structure (BP2) may be in contact with the second connection bump (CB2).

According to some embodiments, interposer substrate (300) may comprise an interlayer insulating layer (311), a wiring structure (312) within the interlayer insulating layer (311), a passivation layer (307) having open portions exposing the wiring structure (312) on the interlayer insulating layer (311), and an upper conductive structure (US) at least partially filling the open portions. Thereafter, connection bumps (CB) may be formed on the upper conductive structure (US). For convenience, a connection bump overlapping a connection region (IR) among the connection bumps (CB) may be referred to as a first connection bump (CB1), and a connection bump overlapping a dummy region (DR) may be referred to as a second connection bump (CB2).

A plurality of semiconductor chips (100, 200) may be aligned on the upper portion of the interposer substrate (300). For example, the first bump structure (BP1) may be aligned vertically with the first connection bump (CB1), and the second bump structure (BP2) may be aligned vertically with the second connection bump (CB2).

According to some embodiments, a plurality of semiconductor chips (100, 200) may be mounted on the interposer substrate (300). Each of the plurality of semiconductor chips (100, 200) may be disposed side by side on the interposer substrate (300) (for example, as illustrated in see FIGS. 1A and 1B). An end portion (for example, p2 in FIG. 2B) of the second bump structure (BP2) may penetrate at least a portion of the first connection bump (CB2). The first bump structure (BP1) may be in contact with the second connection bump (CB1). Accordingly, a semiconductor package (1) may thus be formed.

According to some embodiments, the second connection bump (CB2) may completely surround the second portion (p2) of the second bump structure (BP2) and contact the connection portion (p1b) (or the lower surface) of the first portion (p1), for example as illustrated in FIG. 4A. In this case, a semiconductor package (1a) may be formed.

According to some embodiments, the second connection bump (CB2) may completely surround the second portion (p2) of the second bump structure (BP2) and contact the connection portion (p1b) and the side portion (p1a) of the first portion (p1), for example as illustrated in FIG. 4B. Accordingly, a semiconductor package (1b) may be formed.

According to some embodiments, the second bump structure (BP2) may be formed to have a curved portion. The second bump structure (BP2) may be formed to have, for example, a side portion (p1a) having a shape protruding in a horizontal direction, a connection portion (p1b) having a curved portion, and a second portion (p2a), for example as illustrated in FIG. 4C. Accordingly, a semiconductor package (1c) may be formed.

According to some embodiments, the first bump structure (BP1) and the first connection bump (CB1) may be in contact to form a single shape. In terms of cross-sectional area, the first bump structure (BP1) and the first connection bump (CB1) may form a single curved portion (CS), for example as illustrated in FIG. 4D. Accordingly, a semiconductor package (1d) may be formed.

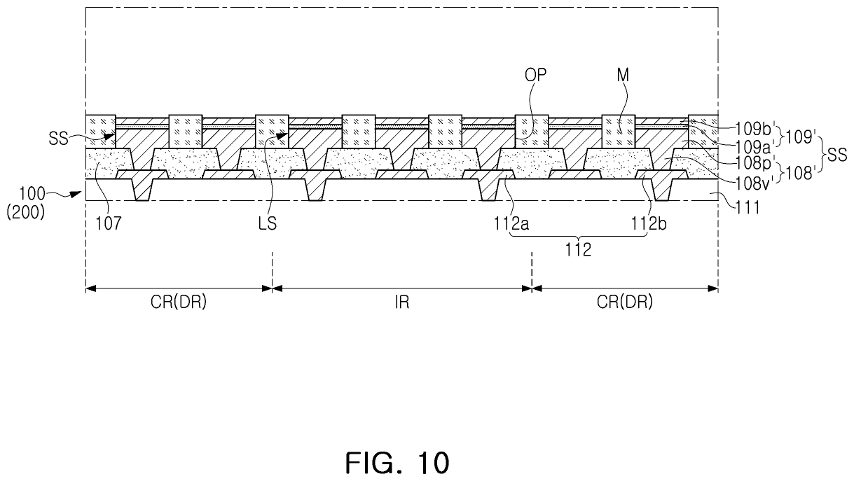

Reference is now made to FIGS. 10 through 12, which are cross-sectional views illustrating a method of manufacturing a semiconductor package (1f) according to an example embodiment according to a process sequence.

Referring to FIG. 10, a lower conductive structure (LS) may be formed on a connection region (IR) of each of a first semiconductor chip (100) and at least one second semiconductor chip (200), and a support structure (SS) may be formed on a dummy region (DR).

A plurality of semiconductor chips (100, 200) including an interlayer insulating layer (111), a wiring structure (112) within the interlayer insulating layer (111), and a lower insulating layer (107) covering the wiring structure (112) on the interlayer insulating layer (111) may be provided. Thereafter, each of the plurality of semiconductor chips (100, 200) may be provided such that the lower surface of the lower insulating layer (107) is face-up.

A plurality of open portions may be formed in the lower insulating layer (107) so that at least a portion of the wiring structure (112) on the connection region (IR) and the dummy region (DR) is exposed. Subsequently, a mask (M) having an opening (OP) may be formed on the lower insulating layer (107) so as to expose the plurality of open portions.

According to some embodiments, a conductive layer (for example, 108′) and a barrier layer (for example, 109′) may be sequentially formed in the opening (OP) to form a lower conductive structure (LS) and a support structure (SS), for example as illustrated in FIG. 6A. The lower conductive structure (LS) and the support structure (SS) may be formed substantially together. Each of the conductive layer and the barrier layer may be formed by an electrolytic plating method.

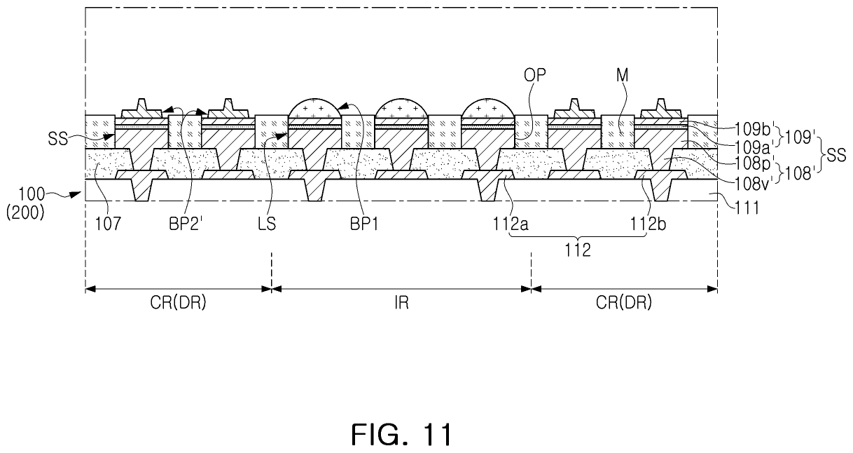

Referring to FIG. 11, a first bump structure (BP1) may be formed on the lower conductive structure (LS), and a second bump structure (BP2′) may be formed on the support structure (SS).

Similar to what was described with reference to FIG. 7, a first bump structure (BP1) may be formed on the lower conductive structure (LS). Similar to what was described with reference to FIG. 8, a second bump structure (BP2′) may be formed on the support structure (SS). The order in which the first and second bump structures (BP1, BP2′) are formed is not particularly limited. For example, the first bump structure (BP1) may be formed after the second bump structure (BP2′) is formed.

Based on the upper surface of the lower insulating layer (107), the uppermost level of the second bump structure (BP2′) may be substantially the same as the uppermost level of the first bump structure (BP1).

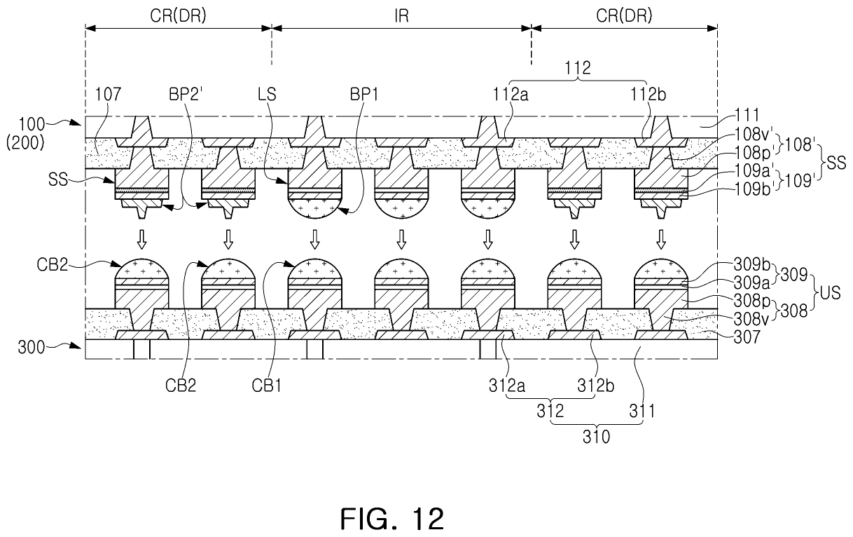

Referring to FIG. 12, an interposer substrate (300) having an upper conductive structure (US) formed thereon may be provided, and first and second connection bumps (CB1, CB2) may be formed on the upper conductive structure (US). Next, a plurality of semiconductor chips (100, 200) may be mounted side by side on an interposer substrate (300). In this case, a first bump structure (BP1) may be in contact with a first connection bump (CB1), and a second bump structure (BP2) may be in contact with a second connection bump (CB2).

An interposer substrate (300) may be provided, which includes an interlayer insulating layer (311), a wiring structure (312) within the interlayer insulating layer (311), and a passivation layer (307) having open portions exposing the wiring structure (312) on the interlayer insulating layer (311), and an upper conductive structure (US) at least partially filling the open portions. Thereafter, connection bumps (CB) may be formed on the upper conductive structure (US). For convenience, a connection bump overlapping a connection region (IR) among connection bumps (CB) may be referred to as a first connection bump (CB1), and a connection bump overlapping a dummy region (DR) may be referred to as a second connection bump (CB2).

A plurality of semiconductor chips (100, 200) may be aligned on an upper portion of an interposer substrate (300). For example, a first bump structure (BP1) may be aligned vertically with a first connection bump (CB1), and a second bump structure (BP2′) may be aligned vertically with a second connection bump (CB2).

Thereafter, a plurality of semiconductor chips (100, 200) may be mounted on an interposer substrate (300). Each of the plurality of semiconductor chips (100, 200) may be disposed side by side on an interposer substrate (300) (for example, as illustrated in FIGS. 1A and 1B). An end of the second bump structure (BP2) may penetrate at least a portion of the second connection bump (CB2) (for example, as illustrated in FIG. 6B). The first bump structure (BP1) may be in contact with the first connection bump (CB1).

As set forth above, according to example embodiments, a semiconductor package having improved reliability and a method of manufacturing the same are provided.

In detail, according to example embodiments, a semiconductor package having improved reliability may be provided by forming a bump structure having a vertically protruding end on a dummy region of a semiconductor chip.

While example embodiments have been illustrated and described above, it will be apparent to those skilled in the art that modifications and variations could be made without departing from the scope of the present disclosure as defined by the appended claims.

What is claimed is:

1. A semiconductor package comprising:
an interposer substrate including upper conductive structures disposed in an upper portion thereof;
connection bumps disposed on the upper conductive structures and including a first connection bump and a second connection bump;
a plurality of semiconductor chips including a first semiconductor chip and at least one second semiconductor chip disposed side by side on the interposer substrate; and
bump structures disposed on the lower portions of each of the first semiconductor chip and the at least one second semiconductor chip and aligned with each of the connection bumps,
wherein the each of the first semiconductor chip and the at least one second semiconductor chip includes:
a first side and a second side;
a dummy region comprising a corner portion formed adjacent to an intersection of the first side and the second side; and
a connection region disposed between the first side and the second side, the connection region being disposed adjacent to the dummy region,
wherein the bump structures include:
a first bump structure disposed on the connection region and contacting the first connection bump; and
a second bump structure disposed on the dummy region, contacting the second connection bump, and including a material different from a material of the first bump structure.

2. The semiconductor package of claim 1, wherein the interposer substrate further includes:
an interlayer insulating layer;
a wiring structure within the interlayer insulating layer; and
a passivation layer disposed on the interlayer insulating layer and including an opening exposing at least a portion of an uppermost wiring pattern of the wiring structure.

3. The semiconductor package of claim 2, wherein each of the upper conductive structures includes:
a conductive layer including a via portion filling the opening of the passivation layer and a pad portion on the via portion; and
a barrier layer including a lower layer on the conductive layer and an upper layer on the lower layer.

4. The semiconductor package of claim 3, wherein the upper layer of the conductive layer and the barrier layer comprises copper (Cu), and
the lower layer of the barrier layer comprises nickel (Ni).

5. The semiconductor package of claim 4, wherein each of the first and second connection bumps comprises an alloy of different conductive materials.

6. The semiconductor package of claim 1, wherein the each of the first semiconductor chip and the at least one second semiconductor chip further includes:
an interlayer insulating layer;
a wiring layer within the interlayer insulating layer;
a lower insulating layer disposed on the interlayer insulating layer and including openings exposing at least a portion of a lowermost wiring pattern of the wiring layer on the connection region; and
a lower conductive structure disposed on the lower insulating layer and at least a portion of which fills the openings, and
the first bump structure is disposed below the lower conductive structure.

7. The semiconductor package of claim 6, wherein the lower conductive structure includes:
a conductive layer including a via portion filling the opening of the lower insulating layer and a pad portion on the via portion; and
a barrier layer on the conductive layer.

8. The semiconductor package of claim 6, wherein the second bump structure includes:
a horizontal portion disposed on the front surface of the dummy region; and
a protrusion protruding downward from at least a portion of the lower surface of the horizontal portion.

9. The semiconductor package of claim 8, wherein the second bump structure is selected from the group consisting of copper (Cu), nickel (Ni), and gold (Au).

10. The semiconductor package of claim 8, wherein the height of the second bump structure is in a range of 20 μm to 25 μm.

11. The semiconductor package of claim 8, wherein the horizontal portion includes:
a convex side surface, and
a lower surface extending from the convex side surface to the protrusion, wherein the lower surface comprises a curved surface.

12. The semiconductor package of claim 8, wherein the second connection bump surrounds at least a portion of the protrusion.

13. The semiconductor package of claim 1, wherein the each of the first semiconductor chip and the at least one second semiconductor chip further includes:
an interlayer insulating layer;
a wiring layer within the interlayer insulating layer;
an insulating layer disposed on the interlayer insulating layer and including open portion exposing at least a portion of a lowermost wiring pattern of the wiring layer;
a lower conductive structure on the connection region, at least a portion of the lower conductive filling at least a portion of the open portion; and
a support structure on the dummy region, at least a portion of the support structure filling at least a portion of the open portion.

14. The semiconductor package of claim 13, wherein each of the lower conductive structure and the support structure includes:
a conductive layer including a via portion filling the open portion and a pad portion on the via portion; and
a barrier layer on the conductive layer,
wherein the first bump structure is disposed below the barrier layer of the lower conductive structure, and
wherein the second bump structure is disposed below the barrier layer of the support structure.

15. A semiconductor package comprising:
a first semiconductor chip having a dummy region and a connection region, and including a lower conductive structure disposed below the connection region;
bump structures including a first bump structure on the lower conductive structure and a second bump structure below the dummy region;
an interposer substrate having the first semiconductor chip mounted thereon and including upper conductive structures disposed in an upper portion thereof;
connection bumps disposed on respective upper portions of the upper conductive structures, and including a first connection bump in contact with the first bump structure and a second connection bump in contact with the second bump structure; and
at least one second semiconductor chip mounted side by side with the first semiconductor chip, on the interposer substrate,
wherein the second bump structure includes a first portion, a width of the first portion becomes smaller toward the second connection bump, and
wherein an end portion of the second bump structure is disposed within the second connection bump.

16. The semiconductor package of claim 15, wherein the first semiconductor chip further includes a first side and a second side,
wherein the dummy region comprises a corner portion formed adjacent to an intersection of the first side and the second side and a central portion formed adjacent to an intersection of a midpoint of the first side and a midpoint the second side, and
wherein the connection region is disposed between the first side and the second side, the connection region being adjacent to the dummy region.

17. The semiconductor package of claim 15, wherein the second bump structure includes:
a first portion; and
a second portion protruding from a lower surface of the first portion and penetrating at least a portion of the second connection bump.

18. The semiconductor package of claim 15, wherein the second connection bump includes an alloy of different conductive materials, and
the second bump structure is selected from the group consisting of copper (Cu), nickel (Ni), and gold (Au).

19. A semiconductor package comprising:
an interposer substrate including upper conductive structures disposed in an upper portion thereof;
a first semiconductor chip disposed on the interposer substrate, having a dummy region and a connection region, and including lower conductive structures disposed below the connection region and facing at least a portion of the upper conductive structures;
at least one second semiconductor chip disposed side by side with the first semiconductor chip, on the interposer substrate;
connection bumps disposed on respective upper portions of the upper conductive structures, and including a first connection bump overlapping the connection region and a second connection bump overlapping the dummy region; and
bump structures including a first bump structure disposed on respective lower portions of the lower conductive structures and contacting the first connection bump, and a second bump structure disposed below the dummy region and vertically penetrating through at least a portion of the second connection bump,
wherein the second bump structure includes a material different from a material of the second connection bump.

20. The semiconductor package of claim 19, wherein an end portion of the second bump structure is spaced apart from the upper surface of each of the upper conductive structures.
